(19) United States
(12) Patent Application Publication
(10) Pub. No.: US 2003/0001655 A1
(43) Pub. Date: Jan. 2, 2003

(54) Level shifter

(75) Inventor: Jong Bae Jeong, Ichon-Shi (JP)

Correspondence Address: MORGAN, LEWIS & BOCKIUS LLP, 1800 M Street, N.W., Washington, DC, 20036, US

(73) Assignee: Hynix Semiconductor Inc.

(21) Appl. No.: 10/026,927

(22) Filed: Dec. 27, 2001

(30) Foreign Application Priority Data
Jun. 28, 2001 (KR) 2001-37795

(51) Int. Cl. H03L 5/00

(52) U.S. Cl. 327/333

(57) ABSTRACT

The present invention relates to a level shifter. The level shifter comprise a first transistor turned on by a control signal, for transmitting Vcc to a first node; a second transistor turned on by the control signal, for transmitting a zero voltage level to the first node; a third transistor turned on by the Vcc, for transmitting the voltage level of the first node to a second node; a fourth transistor turned by the zero voltage level, for transmitting the voltage level of the first node to a third node; a fifth transistor turned on by the voltage level of the second node, for transmitting a first voltage level to an output; and a sixth transistor turned on by the voltage level of the third node, for transmitting a second voltage level to the output.

### BACKGROUND OF THE INVENTION

1. Field of the Invention

The invention relates generally to a level shifter, and more particularly to, a level shifter capable of level-shifting a positive voltage level and a negative voltage level.

2. Description of the Prior Art

Generally, if it is desired to level-shift a level of a given node in a circuit to a zero voltage level, a negative voltage level, a VCC level or a positive high voltage level, a level shifter is employed.

FIG. 1 is a conventional level shifter for level-shifting a zero voltage level to a negative voltage level. An operation of the level shifter in FIG. 1 will be described by reference to FIG. 2.

If a control signal ENb is at HIGH state, a first output node n1 of an inverter INV1 becomes a LOW state. Therefore, a second PMOS transistor MP2 is turned on. An output OUT becomes a Vcc state by turn-on of the second PMOS transistor MP2.

As the output OUT is at a HIGH state, a first NMOS transistor MN1 is turned on while a second NMOS transistor MN2 is kept to be turned off.

On the contrary, if the control signal ENb is changed from a HIGH state to a LOW state, a first PMOS transistor MP1 is turned on and the voltage level of a second node n2 becomes thus a HIGH state. Thus, the second NMOS transistor MN2 is turned on and the output OUT is changed from a Vcc state to a zero voltage level. Next, if the voltage level of VEEX is at a negative voltage level, the output OUT becomes a negative voltage level.

FIG. 3 is a conventional level shifter for level-shifting a Vcc level to a Vpp level. An operation of the level shifter in FIG. 3 will be below described by reference to FIG. 4.

If the control signal EN is at a LOW state, a third output node n3 of a second inverter INV2 is at a HIGH state, so that a fourth NMOS transistor MN4 is turned on. Therefore, a third POMS transistor MP3 is turned on and the output OUT remains a zero voltage level.

On the contrary, if the control signal EN is changed from a LOW state to a HIGH state, a third NMOS transistor MN3 is turned on and a fourth PMOS transistor MP4 is thus turned on, so that the output OUT becomes a Vcc level. At this time, if VPPX is raised from Vcc to Vpp with VPPX being Vcc and the output OUT being Vcc, the output OUT is also changed to Vpp.

FIG. 5 is a conventional level shifter for level-shifting a zero voltage level and a Vcc level to a negative voltage level and a Vpp level, respectively. For explanation's convenience, only a level shift process will be described.

If a control signal INb is at a HIGH state, the first output node n1 of the inverter INV1 becomes a LOW state. As the second PMOS transistor MP2 is turned on, a fifth NMOS transistor MN5 is turned on and the output OUT thus remains a zero voltage level.

Then, if the voltage level of VEEX is lowered from a zero voltage level to a negative level, the output OUT becomes a negative voltage level.

As the third output node n3 of the second inverter INV2 is at a HIGH state when the control signal INb is at LOW state, the fourth NMOS transistor MN4 is turned on and a fifth POMS transistor MP5 is turned on. Therefore, the output OUT is kept to be a Vcc voltage level.

At this time, if VPPX is raised from Vcc to Vpp with VPPX being Vcc and the output OUT being Vcc, the output OUT is also changed to Vpp.

In case of FIG. 5, it can be understood that a transistor constituting the level shifter are so many. If this level shifter is used for a portion of a core circuit in a chip, it could be a severe load.

### SUMMARY OF THE INVENTION

The present invention is contrived to solve the above problem and an object of the present invention is to provide a level shifter capable of reducing the number of a transistor.

In order to accomplish the above object, a level shifter according to the present invention is characterized in that it comprises comprise a first transistor turned on by a control signal, for transmitting VCC to a first node; a second transistor turned on by the control signal, for transmitting a zero voltage level to the first node; a third transistor turned on by the VCC, for transmitting the voltage level of the first node to a second node; a fourth transistor turned by the zero voltage level, for transmitting the voltage level of the first node to a third node; a fifth transistor turned on by the voltage level of the second node, for transmitting a first voltage level to an output; and a sixth transistor turned on by the voltage level of the third node, for transmitting a second voltage level to the output.

### BRIEF DESCRIPTION OF THE DRAWINGS

The aforementioned aspects and other features of the present invention will be explained in the following description, taken in conjunction with the accompanying drawings, wherein:

FIG. 1 is a conventional level shifter for level-shifting a zero voltage level to a negative voltage level;

FIG. 2 is a waveform for describing an operation of the level shifter in FIG. 1;

FIG. 3 is a conventional level shifter for level-shifting a VCC level to a VPP level;

FIG. 4 is a waveform for explaining an operation of the level shifter in FIG. 3;

FIG. 5 is a conventional level shifter for level-shifting a zero voltage level and a Vcc level to a negative voltage level and a Vpp level, respectively;

FIG. 6 is a level shifter according to the present invention; and

FIGS. 7A and 7B are waveforms for explaining an operation of the level shifter in FIG. 6.

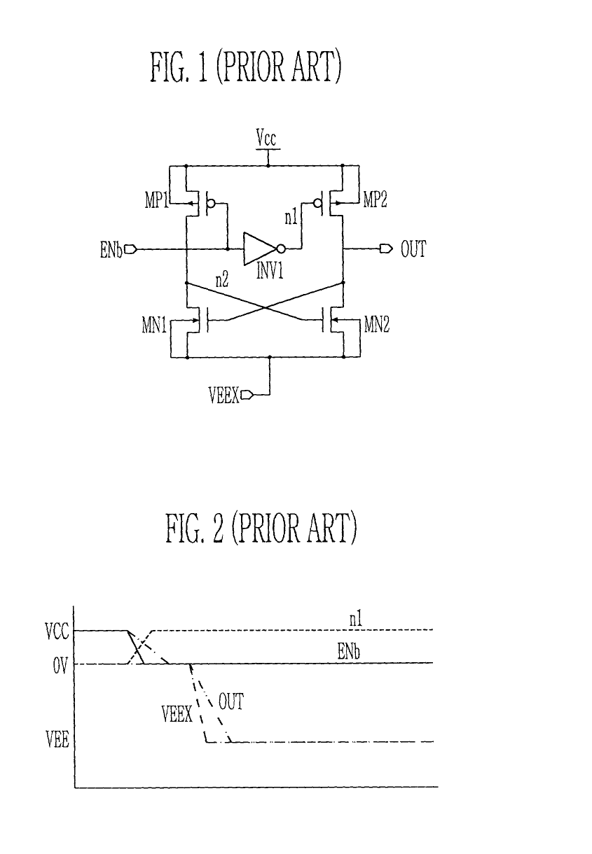

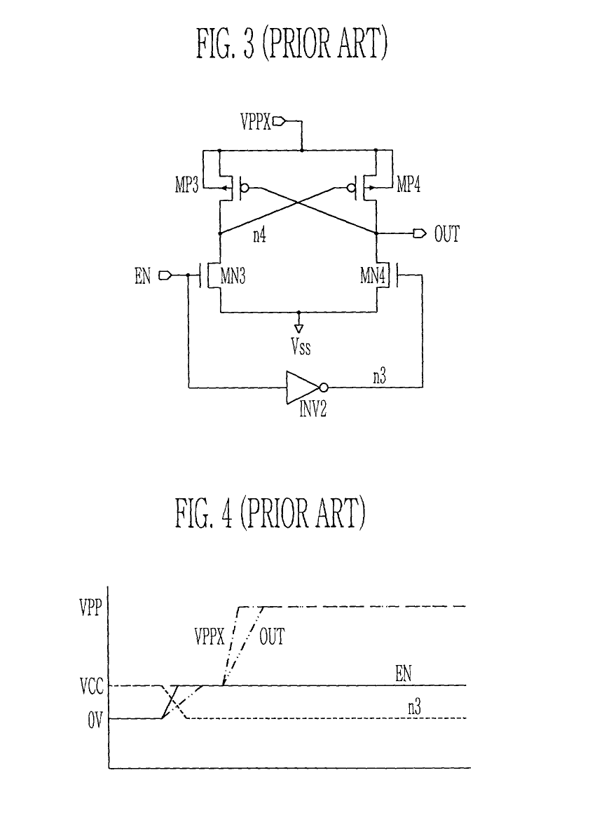

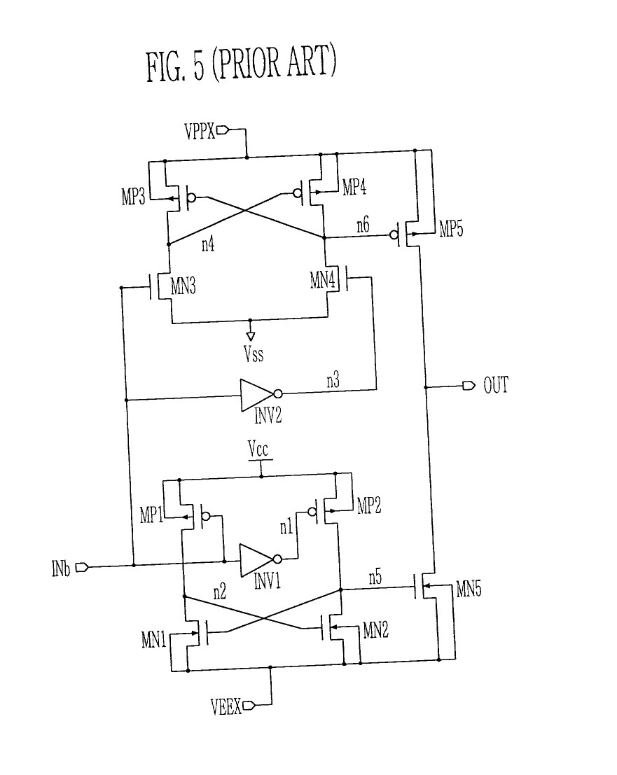

### DETAILED DESCRIPTION OF PREFERRED EMBODIMENTS

The present invention will be described in detail by way of a preferred embodiment with reference to accompanying drawings.

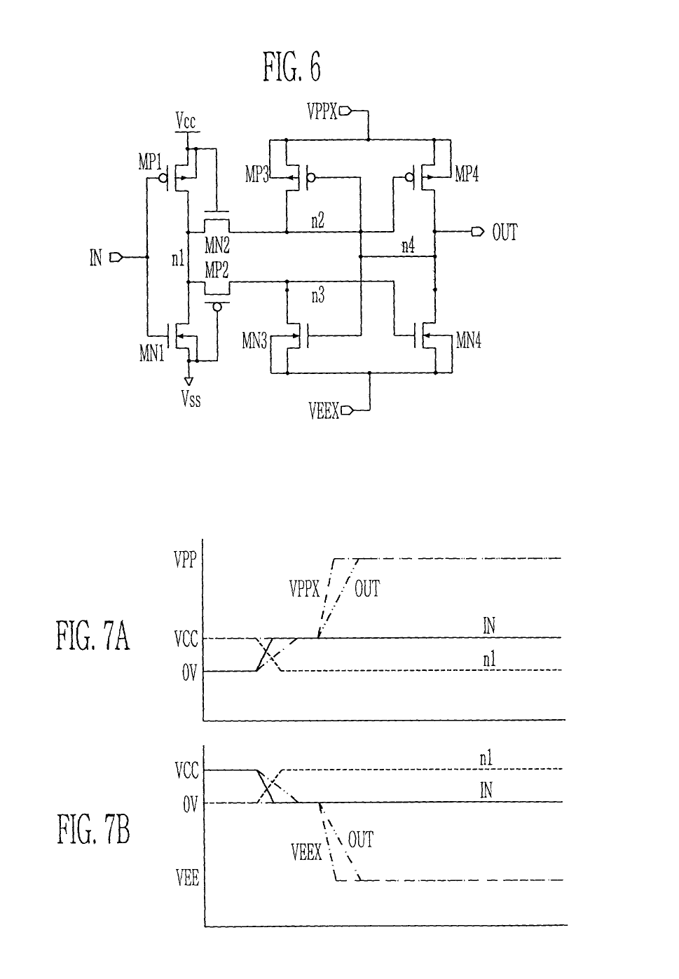

FIG. 6 is a level shifter according to the present invention. An operation of the level shifter in FIG. 6 will be described by reference to FIGS. 7A and 7B.

Initially, VPPX is set to a VCC level and VEEX is set to a zero level.

As shown in FIG. 7A, if a control signal IN become a HIGH state, as a first NMOS transistor MN1 is turned on, a first node n1 becomes a LOW state and a second PMOS transistor MP2 is turned on, so that a third node n3 becomes a Vtp state. Also, a second NMOS transistor MN2 is turned on and a second node n2 becomes a LOW state. Thus, a fourth NMOS transistor MN4 is turned off while a fourth PMOS transistor MP4 is turned on, so that a fourth node n4 becomes a HIGH state. As a third NMOS transistor MN3 is turned on, the fourth NMOS transistor MN4 is completely turned off, so that the output OUT becomes a VPPX state. Next, if VPPX is raised from Vcc to Vpp, the output is also raised to Vpp.

As shown in FIG. 7B, if the control signal IN is at a LOW state, a first PMOS transistor MP1 is turned on and the first node n1 becomes a HIGH state. Thus, the second NMOS transistor MN2 is turned on and the second node n2 becomes a Vcc-Vtn state, so that the fourth PMOS transistor MP4 is almost turned off. In addition, as the second PMOS transistor MP2 is turned on and the third node n3 becomes a HIGH state, the fourth NMOS transistor MN4 is turned on. Therefore, as the voltage level of the fourth node n4 becomes a zero voltage level, a third PMOS transistor MP3 is turned on and the fourth PMOS transistor MP4 is thus completely turned off, so that VEEX is transmitted to the output OUT. If VEEX is lowed from a zero voltage level to a negative voltage level VEE, the output OUT is also lowered to VEE.

As mentioned above, the present invention has an advantage that it can implement a level shifter of various levels such as positive and negative voltage and the like by using a small number of transistor compared to a conventional level shifter.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A level shifter, comprising:
a first transistor turned on by a control signal, for transmitting Vcc to a first node;
a second transistor turned on by said control signal, for transmitting a zero voltage level to said first node;
a third transistor turned on by said Vcc, for transmitting the voltage level of said first node to a second node;
a fourth transistor turned by said zero voltage level, for transmitting the voltage level of said first node to a third node;
a fifth transistor turned on by the voltage level of said second node, for transmitting a first voltage level to an output; and
a sixth transistor turned on by the voltage level of said third node, for transmitting a second voltage level to said output.

2. The level shifter as claimed in claim 1, wherein said first, fourth and fifth transistors are formed of a PMOS transistor.

3. The level shifter as claimed in claim 1, wherein said second, third and sixth transistors are formed of a NMOS transistor.

4. The level shifter as claimed in claim 1, further including a seventh transistor turned when said output is VPPX, for making the voltage level of said third node completely a zero voltage level.

5. The level shifter as claimed in claim 4, wherein said seventh transistor is formed of a NMOS transistor.

6. The level shifter as claimed in claim 1, further including an eighth transistor turned when said output is VEEX, for making the voltage level of said second node a Vcc state.

7. The level shifter as claimed in claim 6, wherein said eighth transistor is formed of a PMOS transistor.
